(19) United States
(12) Patent Application Publication
(10) Pub. No.: US 2006/0138628 A1
(43) Pub. Date: Jun. 29, 2006

(54) Stack chip package

(75) Inventor: Chung-Hsing Tzu, Taipei (TW)

Correspondence Address: BIRCH STEWART KOLASCH & BIRCH, PO BOX 747, FALLS CHURCH, VA, 22040-0747, US

(73) Assignee: Domintech Co., Ltd.

(21) Appl. No.: 11/159,152

(22) Filed: Jun. 23, 2005

(30) Foreign Application Priority Data
Dec. 24, 2004 (TW) 093220896

(51) Int. Cl. H01L 23/02

(52) U.S. Cl. 257/686

(57) ABSTRACT

An improved stack chip package comprising a lead frame, chip, plural leads and coating, among which: the lead frame is made of metal materials through impact extrusion forming two or four lines of rectangular plural pins comprising three lead segments making the pin [symbol] -shaped; So install a chip on the first segment's inside surface, bond wires at the chip's bond pads and each segment will form an electrical connection, coat the part where the lead is jointed for the completion of sealing operation, i.e. the chip's upper and lower sides can be connected to another chip package by the contact of the first and second segments, and the chip package can be stacked freely besides reduced volume and strengthened data processing performance.

### FIELD OF THE PRESENT INVENTION

The present invention provides a kind of improved stack chip package, particularly a kind of improved structure of chip package that can be cascaded at will.

### BACKGROUND OF THE PRESENT INVENTION

Nowadays a good many of electric products such as mobile phone, MP3 Walkman, portable disc, digital camera, Personal Digital Assistant (PDA), have been more delicate and multipurpose, which would be used for digital photography, record, data storage etc., besides their main functions. Therefore an improved functional chip package for the application of such functions is required, and the electric product would be small in size and of good efficiency in multifunction.

The prior chip package (as shown in FIG. 8) consists of a chip10, a lead frame20, plural leads30 and coating40. Usually such package makes the lead frame20 form two or four rectangular pins201 side by side. Or a convex block22 was designed at the end of rectangular pins201 for external electric conduction. Thereby install the chip10 on the lead frame20, and form an insulating coating on the lead30 area for sealing after bonding the lead30 on the chip 10 with the inside end of the pin201 for an electrical connection, and the chip package is obtained by means of connecting the plural pins201 of the lead frame20 with the circuit boards of electrical devices.

The abovementioned prior chip package must be connected to the circuit board of electronic products with the lead frame20. When we install the plural chip package on a circuit board, they must be connected side by side. Especially when electronic products are required to have the small size and various functions as the abovementioned ones, such installation certainly will increase the numbers of paralleled chips and further make electronic products not be a simple structure or have limited functions. In such case, it would lag behind the trends in this field.

### SUMMARY OF THE PRESENT INVENTION

A primary purpose of the present invention is to provide an improved cascade chip package. Based on the improvement in pins and chip-fixing position, plural chip package can be cascaded with further free more space and strengthen data processing performance.

As the abovementioned purposes, the present invention consists of a lead frame, a chip, plural leads and coating, among which: the lead frame is made of metal materials by means of impact stamping or etching forming two or four lines of rectangular plural pins. Each pin comprises three segments, i.e. first lead segment, second lead segment and connecting part connected to the first and second lead segment, making the pin [symbol] -shaped; the chip is the electronic component made of prior semiconductor materials; the lead is the metal conductor and the coating epoxy is made from an nonconductive material. So install a chip on the inside surface of the first wire segment of the lead frame, bond conductive wires at the bond pad of the chip and each lead segment on one side to form an electrical connection, coat the part around the chip where the lead is jointed for the completion of sealing operation, i.e. the upper and lower sides of the chip can be connected to another chip package by the contact of the first and second lead segments, and the chip package can be stacked at will, besides its reduced volume and strengthened data processing performance.

### METHODS OF APPLICATION

The embodiment presents the structural characteristics, functions and purposes of the present invention with drawings as follows:

As shown in FIG. 1-A, 1-B and 2, the present invention provides a kind of improved cascade chip package, comprising a lead frame1, a chip2, plural leads3 and coating4, among which: the lead frame1 is made of metal materials by means of impact extrusion or etching forming two lines in parallel (as shown in FIG. 4) or four lines of matrix plural pins11 (as shown in FIG. 5). Each pin11 comprises three segments, i.e. first lead segment111, second lead segment112 and connecting part113 connected to the first and second lead segment (as shown in FIG. 3), making the pin [symbol] -shaped;

The chip2, as shown in FIG. 1-A and 1-B, is the electronic component made of prior semiconductor materials. And plural electrical connection contact21 was set on the selected surface;

The lead3 is the metal conductor, which may be wire etc.; and

The coating4 is an insulating nonconductive compound material for sealing the chip package2.

Thereby, as shown in FIG. 1-A and 1-B, install a chip2 on the inside surface of the first lead segment111 of the lead frame1, mount leads3 at the contact of the chip2 and each lead segment111 on one side to form an electrical connection, coat the part around the chip2 where the lead is jointed in order to complete sealing operation, i.e. make the first and second lead segments111,112 and connecting part113 bare on the chip2 and the two surfaces and sides of the coating4, and then the obtained plural chips 2 can be stacked and continued through each pin 11 of the lead frame 1 (as shown in FIG. 2). Because the upper and lower sides of the chip2 have exposed jutted pin11 comprising first and second lead segment111, 112, the plural chip package can be stacked at will by manufacturers and installed onto the electric boards of other electronic products to free more space, exert functions to the utmost, such as abovementioned digital photography, record, data storage and so on, and strength data processing performance.

In addition, in this invention, the connecting part113 of each pin11 of the lead frame1 has been jutted on two sides of the chip2 and the coating4. In case of side by side design requirement, the improved chips can be contacted with each other on the connecting part113 based on proper circuit design for forming an electrical connection (as shown in FIG. 6) and to further free more space from circuit boards and ensure the demands for small size and multifunction upon the electronic products at present and in the future.

Furthermore, as shown in FIG. 7, the coating4 is not designed to seal the chip 2 absolutely and it can be installed onto the two sides of the chip 2 to make the top of the chip2 hollowed and further to shorten the distance between the first and second wire segment111, 112 of each pin11 of the lead frame1 and to provide smaller and thinner chip package for the application of electronic products.

In summary, this Improved Stack Chip Package is innovative and practical. Its methods of application are also original and its functions conform to its design purpose. Therefore we apply for this patent in accordance with the relevant laws and expect your juror to make a scrutiny into it and ratify the patent early. And we shall be very glad to reciprocate your any help.

### BRIEF DESCRIPTION OF THE DRAWINGS

FIG. 1-A is the Cutaway View I of the Present Invention

FIG. 1-B is the Cutaway View II of the Present Invention

FIG. 2 is the Three-dimensional Diagram of the Present Invention

FIG. 3 is the Sketch Map of Pins of the Lead Frame of the Present Invention

FIG. 4 is the Sketch Map of Pins in Twin-Row Package of the Present Invention

FIG. 5 is the Sketch Map of Pins in Matrix Package of the Present Invention

FIG. 6 is the Sketch Map of Chip Package in side by side connection of the Present Invention

FIG. 7is the Cutaway View of another Embodiment of the Present Invention

FIG. 8 is the Cutaway View of the Prior Chip Package

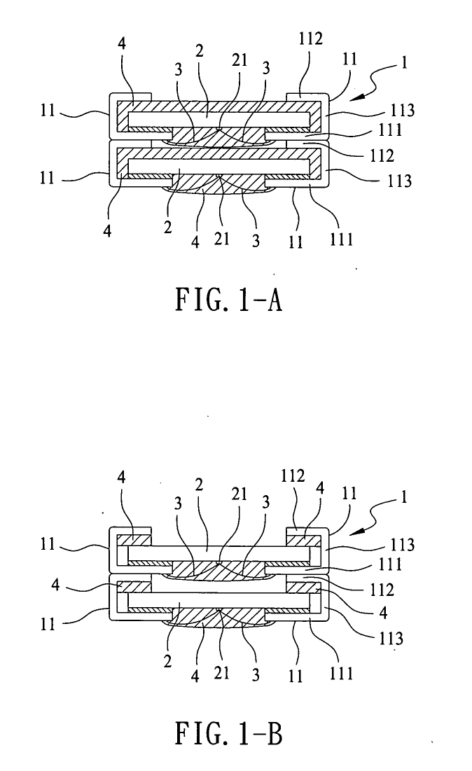

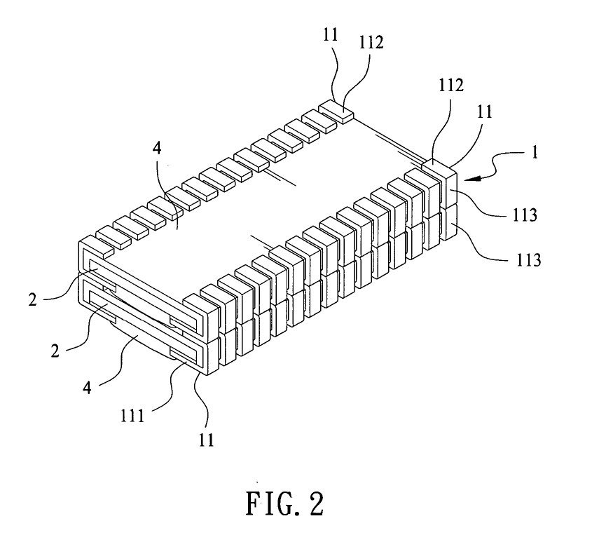

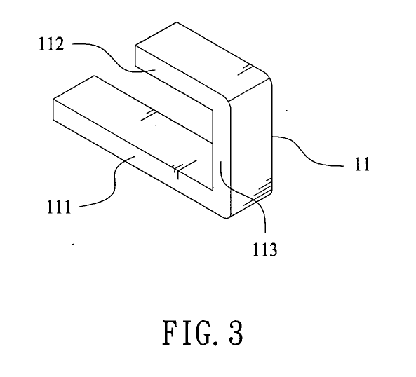

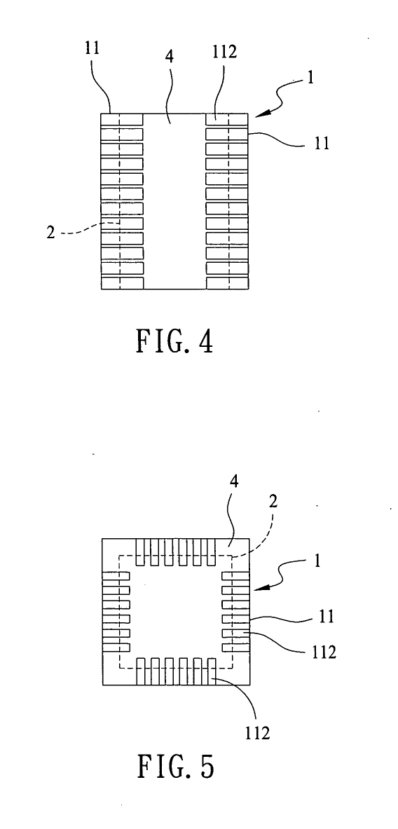

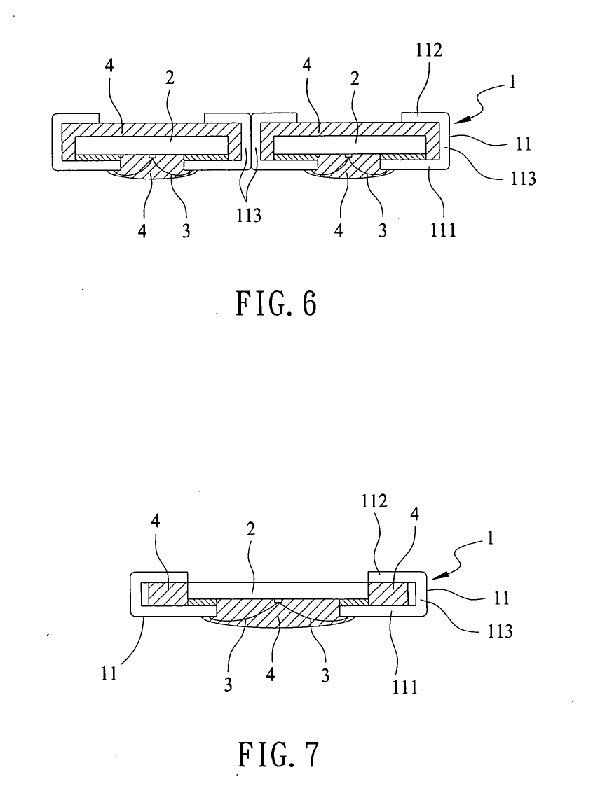

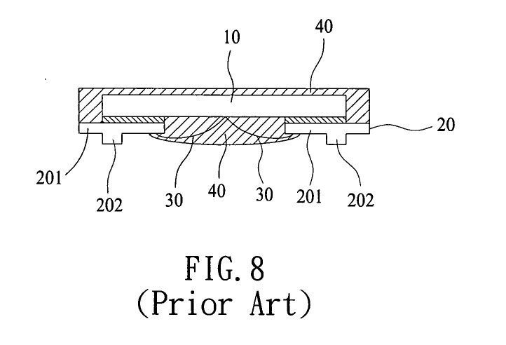

### BRIEF DESCRIPTION OF THE FIGURE NUMBER

| | |
|---|---|
| Lead Frame 1 | Pins 11 |
| First Section 111 | Second Section 112 |
| Connection 113 | Chip 2 |
| Contact 21 | Lead 3 |
| Coating 4 | |

What is claimed is:

1. An improved stack chip package consists of a lead frame, a chip, plural leads and coating, featuring:
a lead frame consists of plural pins in rows. Each pin comprises three segments, i.e. first lead segment, second lead segment and connecting part connected to the first and second lead segment. Thereby, install a chip on the inside surface of the first segment of each pin of the lead frame and fix it, bond conductive wire at the bond pads of the chip and each segment of pins respectively to form an electrical connection, coat the part around the chip where the lead is jointed to complete the sealing operation and to have the first and second lead segment and the connecting part jutted on the both surfaces and sides of the chip, and then the obtained plural chip package can be stack through each pin of the lead frame.

2. The improved stack chip package as claimed in claim 1, wherein said the plural pins include two types, twin-row parallel and four-row matrix.

3. The improved stack chip package as claimed in claim 1 or 2, wherein said the coating includes the sealing part around the chip.

4. The improved stack chip package as claimed in claim 1 or 2, wherein said the coating includes the hollowed part of the chip that is formed with sealing part on the one side of the chip.

5. The improved stack chip package as claimed in claim 1 or 2, wherein said the chip package includes the connecting part where the chip can be connected to another chip package.
